(19) United States
(12) Patent Application Publication
(10) Pub. No.: US 2026/0299406 A1
(43) Pub. Date: Oct. 1, 2026

(54) PHOTORESIST COMPOSITIONS AND PATTERNING METHODS

(71) Applicants: DuPont Electronic Materials International, LLC, Marlborough, MA (US); DuPont Electronics, Inc., Wilmington, DE (US)

(72) Inventors: Deyan Wang, Hudson, MA (US); Wenxu Zhang, Wellesley, MA (US); Adam Z. Peng, Schenectady, NY (US); Zhebin Zhang, Westborough, MA (US); Gregory Cleveland, Wilmington, DE (US); Greg A. Hostetler, Newark, DE (US); Rachel Snyder, West Boylston, MA (US)

(21) Appl. No.: 19/392,560

(22) Filed: Nov. 18, 2025

Related U.S. Application Data
(63) Continuation-in-part of application No. 19/083,155, filed on Mar. 18, 2025, now abandoned.

(51) Int. Cl. G03F 7/004; G03F 7/00; G03F 7/16

(52) U.S. Cl. CPC G03F 7/0042; G03F 7/0045; G03F 7/168; G03F 7/70033

(57) ABSTRACT

A photoresist composition, comprising an organic metal oxide oligomer comprising a M-O-M bond, wherein M comprises a metal; a crosslinker comprising a photocleavable group, wherein the crosslinker is structurally different from the organic metal oxide oligomer; and a solvent, wherein the solvent is present in the composition in an amount greater than 50 weight (wt %), based on total weight of the composition.

### CROSS-REFERENCE TO RELATED APPLICATIONS

This application is a continuation-in-part of U.S. application Ser. No. 19/083,155, filed on Mar. 18, 2025, in the United States Patent and Trademark Office, the content of which is incorporated herein in its entirety by reference.

### FIELD

The present invention relates to photoresist compositions and to pattern formation methods using such photoresist compositions. The invention finds particular applicability in lithographic applications in the semiconductor manufacturing industry.

### BACKGROUND

Photoresist compositions are photosensitive materials used to transfer a pattern to one or more underlying layers, such as a metal, semiconductor, or dielectric layer disposed on a substrate. Positive-tone chemically amplified photoresist compositions are conventionally used for high-resolution patterning. Such resist compositions typically include a polymer having acid-labile groups and a photoacid generator (PAG). A layer of the photoresist composition is pattern-wise exposed to activating radiation and the PAG generates an acid in the exposed regions. During post-exposure baking, the acid causes cleavage of the polymer's acid-labile groups and a resulting polarity-switch of the polymer in the exposed regions. This creates a difference in solubility characteristics between exposed and unexposed regions of the photoresist layer in a developer solution. In a positive tone development (PTD) process, exposed regions of the photoresist layer become soluble in a developer, typically an aqueous base developer, and are removed from the substrate surface while unexposed regions remain on the substrate to form a positive relief image. Alternatively, in a typical negative tone development (NTD) process, unexposed regions of the photoresist layer can be removed with an organic solvent developer, typically n-butyl acetate, while the exposed regions remain on the substrate to form a negative relief image. The resulting relief image permits selective processing of the substrate.

As an attempt to achieve higher sensitivity to extreme ultraviolet (EUV) wavelengths and below and improve the etch resistance of photoresists, it has been considered in recent years to use an organic metal material to incorporate metal atoms into photoresists. A compound that contains a metallic element such as antimony, bismuth, cobalt, gallium, germanium, indium, manganese, tellurium, thallium, tin, tungsten, vanadium, and/or zinc has higher etch resistance to a desired etch chemistry and may have a higher absorbance of EUV light compared to an organic material that does not contain the metal (or metalloid or semi-metal, although the term “metal” is used herein to cover metals, metalloids, and semi-metals), and improvement of etch resistance and photosensitivity of photoresists can be expected.

There is a continuing need for photoresist compositions that address one or more problems associated with the state of the art, and for patterning methods using such photoresist compositions.

### SUMMARY

An aspect provides a photoresist composition, comprising: an organic metal oxide oligomer comprising a M-O-M bond, wherein M includes a metal; a crosslinker including a photocleavable group, wherein the crosslinker is structurally different from the organic metal oxide oligomer; and a solvent, wherein the solvent is present in the composition in an amount greater than 50 weight (wt %), based on total weight of the composition.

Another aspect provides a pattern formation method that includes (a) applying a layer of the photoresist composition on a substrate to form a photoresist composition layer; (b) soft-baking the photoresist composition layer to crosslink the organic metal oxide oligomer and the crosslinker to form a soft-baked photoresist composition layer; (c) exposing the soft-baked photoresist composition layer to activating radiation to form a post-exposure photoresist composition layer; and (d) developing the post-exposure photoresist composition layer to provide a resist relief image.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. The modifier “about” used in connection with a quantity is inclusive of the stated value and has the meaning dictated by the context (e.g., includes the degree of error associated with measurement of the particular quantity). All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl-O—”; “carboxyl” and “carboxylic acid group” refer to a group having the formula “—C(O)—OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl-O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel's Rule (4n+2 π electrons) and includes carbon atoms in the ring; the term “heteroaromatic group” refers to an aromatic group that includes one or more heteroatoms (e.g., 1-4 heteroatoms) selected from N, O, and S instead of a carbon atom in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl-O—”; and “arylthio” refers to “aryl-S—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; “heteroalkyl” refers to an alkyl group having at least one heteroatom instead of carbon; “heterocycloalkyl” refers to a cycloalkyl group having 1-4 heteroatoms as ring members instead of carbon; “heterocycloalkylene” refers to a heterocycloalkyl group having a valence of two; “heteroaryl” refers to an aromatic 4-8 membered monocyclic, 8-12 membered bicyclic, or 11-14 membered tricyclic ring system having 1-4 heteroatoms (if monocyclic), 1-6 heteroatoms (if bicyclic), or 1-9 heteroatoms (if tricyclic) that are each independently selected from N, O, S, Si, or P (e.g., carbon atoms and 1-3, 1-6, or 1-9 heteroatoms of N, O, or S, if monocyclic, bicyclic, or tricyclic, respectively). Examples of heteroaryl groups include pyridyl, furyl (furyl or furanyl), imidazolyl, benzimidazolyl, pyrimidinyl, thiophenyl or thienyl, quinolinyl, indolyl, thiazolyl, and the like; and “heteroarylene” refers to a heteroaryl group having a valence of two.

The term “halogen” means a monovalent substituent that is fluorine (fluoro), chlorine (chloro), bromine (bromo), or iodine (iodo). The prefix “halo” means a group including one or more of a fluoro, chloro, bromo, or iodo substituent instead of a hydrogen atom. A combination of halo groups (e.g., bromo and fluoro), or only fluoro groups may be present. For example, the term “haloalkyl” refers to an alkyl group substituted with one or more halogens. As used herein, “substituted C₁₋₈ haloalkyl” refers to a C₁₋₈ alkyl group substituted with at least one halogen, and is further substituted with one or more other substituent groups that are not halogens. It is to be understood that substitution of a group with a halogen atom is not to be considered a heteroatom-containing group, because a halogen atom does not replace a carbon atom.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom's normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl (C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O)H), carboxylic acid or an alkali metal or ammonium salt thereof, esters (including acrylates, methacrylates, and lactones) such as C₂₋₆ alkyl esters (—C(O)O-alkyl or —OC(O)-alkyl) and C₇₋₁₃ aryl esters (—C(O)O-aryl or —OC(O)-aryl); amido (—C(O)NR₂ wherein R is hydrogen or C₁₋₆ alkyl), carboxamido (—CH₂C(O)NR₂ wherein R is hydrogen or C₁₋₆ alkyl), halogen, thiol (—SH), C₁₋₆ alkylthio (—S-alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂-alkyl), C₆₋₁₂ arylsulfonyl (—S(O)₂-aryl), or tosyl (CH₃C₆H₄SO₂—).

As used herein, when a definition is not otherwise provided, a “divalent linking group” refers to a divalent group including one or more of —O—, —S—, —Te—, —Se—, —C(O)—, —C(O)O—, —N(R′)—, —C(O)N(R′)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R′)—, —C(O)N(R′)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. More typically, the divalent linking group includes at least one of —O—, —C(O)—, —C(O)O—, —N(R′)—, —C(O)N(R′)—, substituted or unsubstituted C₁₋₁₀ alkylene, substituted or unsubstituted C₃₋₁₀ cycloalkylene, substituted or unsubstituted C₃₋₁₀ heterocycloalkylene, substituted or unsubstituted C₆₋₁₀ arylene, substituted or unsubstituted C₃₋₁₀ heteroarylene, or a combination thereof, wherein R is hydrogen, substituted or unsubstituted C₁₋₁₀ alkyl, substituted or unsubstituted C₁₋₁₀ heteroalkyl, substituted or unsubstituted C₆₋₁₀ aryl, or substituted or unsubstituted C₃₋₁₀ heteroaryl.

As used herein, an “acid-labile group” refers to a group in which a bond is cleaved by the action of an acid, optionally and typically with thermal treatment, resulting in formation of a polar group, such as a carboxylic acid or alcohol group. In some instances, the acid-labile group may be formed on a polymer, and optionally and typically with a moiety connected to the cleaved bond becoming disconnected from the polymer. In other systems, a non-polymeric compound may include an acid-labile group that may be cleaved by the action of an acid, resulting in formation of a polar group, such as a carboxylic acid or alcohol group on a cleaved portion of the non-polymeric compound. Such acid is typically a photo-generated acid with bond cleavage occurring during post-exposure baking (PEB); however, embodiments are not limited thereto, and, for example, such acid may be thermally generated. Suitable acid-labile groups include, for example: tertiary alkyl ester groups, secondary or tertiary ester groups having aryl groups, secondary or tertiary ester groups having a combination of alkyl and aryl groups, tertiary alkoxy groups, acetal groups, or ketal groups. Acid-labile groups are also commonly referred to in the art as “acid-cleavable groups,” “acid-cleavable protecting groups,” “acid-labile protecting groups,” “acid-leaving groups,” “acid-decomposable groups,” and “acid-sensitive groups.”

As used herein, the term “metal” includes metals, metalloids, and semi-metals.

In some embodiments, the organic metal oxide oligomer has a backbone that includes structural units of the formula -(M-O)—, wherein each structural unit may further independently include one or more additional ligands bonded to the metal of the backbone as described herein.

Provided is a photoresist composition including an organic metal oxide oligomer including an M-O-M bond, wherein M includes a metal; a crosslinker including a photocleavable group, wherein the crosslinker is structurally different from the organic metal oxide oligomer; and a solvent, wherein the solvent is present in the photoresist composition in an amount greater than 50 weight percent (wt %), based on total weight of the photoresist composition.

The metal-containing resist material provides high sensitivity and high resolution, particularly in EUV and electron beam lithography. Because the photoresist composition is derived from a photocleavable crosslinker, the cured composition can be used to form a photoresist layer, wherein the solubility is increased by the photoinitiated cleavage of the photocleavable crosslinker moiety.

The solvent is included in the photoresist composition for dissolving the components of the composition and to facilitate its coating on a substrate. Preferably, the solvent is an organic solvent conventionally used in the manufacture of electronic devices. Suitable solvents include, for example: alcohols such as methanol, ethanol, 1-propanol, iso-propanol, tert-butanol, 2-methyl-2-butanol, 4-methyl-2-pentanol, and diacetone alcohol (4-hydroxy-4-methyl-2-pentanone) (DAA); propylene glycol monomethyl ether (PGME); ethers such as diethyl ether, tetrahydrofuran, 1,4-dioxane, and anisole; ketones such as acetone, methyl ethyl ketone, methyl iso-butyl ketone, 2-heptanone, acetylacetone (AcAc), and cyclohexanone (CHO); esters such as ethyl acetate, n-butyl acetate, propylene glycol monomethyl ether acetate (PGMEA), ethyl lactate (EL), hydroxyisobutyrate methyl ester (HBM), and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; low molecular weight carboxylic acids such as acetic acid, propanoic acid, or butyric acid; water; cyclopentanone, hexanone, pentanone; or a combination thereof. Of these, preferred solvents are PGME, PGMEA, EL, GBL, HBM, CHO, DAA, AcAc, or a combination thereof. In some embodiments, the solvent may be a hydroxyl-containing solvent, a carbonyl-containing solvent, or a combination thereof, preferably having a boiling point of less than 200° C.

The solvent may be any suitable solvent that can provide the organic metal oxide oligomer (e.g., the hydroxyl-containing solvent and/or the carbonyl-containing may be any suitable solvent). For example, the solvent may have a structure that is represented by Formula 1:

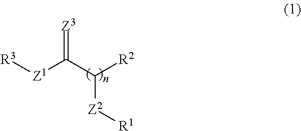

In Formula (1), Z¹ and Z² are each independently O or S. Typically, Z¹ and Z² are 0.

In Formula (1), n is an integer from 1 to 3. Typically, n is 1 or 2, preferably 1.

In Formula (1), R¹ is hydrogen, deuterium, substituted or unsubstituted C₁₋₃₀ alkyl, or substituted or unsubstituted C₃₋₃₀ cycloalkyl. Typically, R¹ is hydrogen, or substituted or unsubstituted C₁₋₃₀ alkyl, preferably hydrogen.

In Formula (1), R² is hydrogen, deuterium, halogen, substituted or unsubstituted C₁₋₃₀ alkyl, substituted or unsubstituted C₁₋₃₀ alkoxy, substituted or unsubstituted C₃₋₃₀ cycloalkyl, substituted or unsubstituted C₆₋₃₀ aryl, substituted or unsubstituted C₆₋₃₀ aryloxy, substituted or unsubstituted C₃₋₃₀ heteroaryl, or substituted or unsubstituted C₃₋₃₀ heteroaryloxy. Typically, R² is hydrogen, substituted or unsubstituted C₁₋₃₀ alkyl, substituted or unsubstituted C₃₋₃₀ cycloalkyl, substituted or unsubstituted C₆₋₃₀ aryl, or substituted or unsubstituted C₃₋₃₀ heteroaryl, preferably hydrogen, substituted or unsubstituted C₁₋₃₀ alkyl.

In Formula (1), R³ is hydrogen, deuterium, substituted or unsubstituted C₁₋₃₀ alkyl, substituted or unsubstituted C₃₋₃₀ cycloalkyl, substituted or unsubstituted C₆₋₃₀ aryl, or substituted or unsubstituted C₃₋₃₀ heteroaryl. Typically, R³ is hydrogen, substituted or unsubstituted C₁₋₃₀ alkyl, substituted or unsubstituted C₃₋₃₀ cycloalkyl, or substituted or unsubstituted C₆₋₃₀ aryl, preferably hydrogen, or substituted or unsubstituted C₁₋₃₀ alkyl.

In some embodiments, the solvent may have a structure that is represented by Formula (l a):

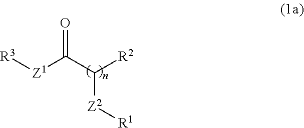

In Formula (1a), Z¹, R¹, R², and R³ are each as defined in Formula (1).

In some embodiments, the solvent may have a structure that is represented by Formula (1b):

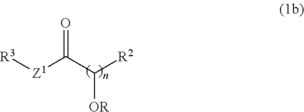

In Formula (1b), Z¹, R¹, R², and R³ are each as defined in Formula (1).

In some embodiments, the solvent may be methyl lactate, ethyl lactate, butyl lactate, or the like, or a combination thereof.

The total solvent content (i.e., cumulative solvent content for all solvents) in the photoresist compositions is typically from 50 to 99 wt %, for example, from 60 to 99 wt %, or from 85 to 99 wt %, based on total weight of the photoresist composition. The desired solvent content will depend, for example, on the desired thickness of the coated photoresist layer and the coating conditions.

The organic metal oxide oligomer includes an M-O-M bond, wherein M includes a metal. In some embodiments, M includes antimony, bismuth, cobalt, gallium, germanium, indium, manganese, tellurium, thallium, tin, tungsten, vanadium, zinc, or a combination thereof. For example, M may be tin, germanium, or antimony, typically tin or antimony, and preferably tin. In some embodiments, the organic metal oxide oligomer may include more than one M-O-M bond, for example, from 2 to 1000 M-O-M bonds, from 2 to 500 M-O-M bonds, from 2 to 250 M-O-M bonds, from 2 to 100 M-O-M bonds, from 2 to 50 M-O-M bonds, from 2 to 25 M-O-M bonds, or from 2 to 10 M-O-M bonds.

The organic metal oxide oligomer may have any suitable structure. In some embodiments, the organic metal oxide oligomer may be of Formula (2):

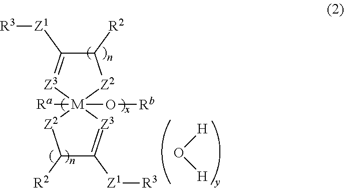

In Formula (2), Z¹, Z², Z³, R², and R³ are each as defined in Formula (1).

In Formula (2), each M is independently antimony, bismuth, cobalt, gallium, germanium, indium, manganese, tellurium, thallium, tin, tungsten, vanadium, or zinc. For example, each M may be independently tin, germanium, indium, antimony, tellurium, or bismuth. Typically, each M is independently tin, germanium, antimony, tellurium, or bismuth.

In Formula (2), R^{a} is halogen, hydroxyl, or a solvent group. For example, the solvent group R^{a} may be represented by Formula (1c):

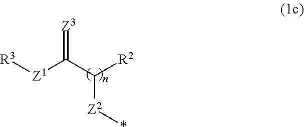

wherein Z¹, Z², Z³, R², and R³ are each as defined in Formula (1), and * indicates a binding site to M. Typically, R^{a} is hydroxyl or a group of Formula (1c).

In Formula (2), R^{b} is hydrogen or a solvent group. For example, R^{b} may be a solvent group that is represented by Formula (1d):

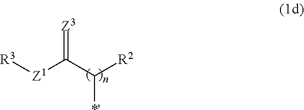

wherein Z¹, Z², Z³, R², and R³ are each as defined in Formula (1), and *′ indicates a binding site to O. Typically, R^{b} is a group of Formula (1d).

In Formula (2), x is an integer from 2 to 200, from 2 to 100, from 2 to 50, from 2 to 25, from 2 to 10, or from 2 to 5.

In Formula (2), y is from 0 to 10, or from 1 to 6, or from 2 to 4.

In some embodiments, the organic metal oxide oligomer may be of Formula (2a):

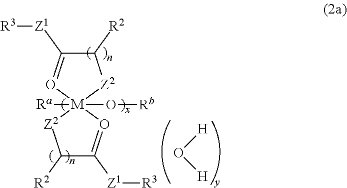

In Formula (2a), Z¹, Z², R², and R³ are each as defined in Formula (1).

In Formula (2a), M, R^{a}, R^{b}, x, and y are each as defined in Formula (2).

In some embodiments, the organic metal oxide oligomer may be of Formula (2b):

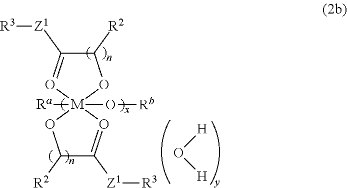

In Formula (2b), Z¹, R², and R³ are each as defined in Formula (1).

In Formula (2b), M, R^{a}, R^{b}, x, and y are each as defined in Formula (2).

Exemplary organic metal oxide oligomers may include one or more of the following, although embodiments are not limited thereto:

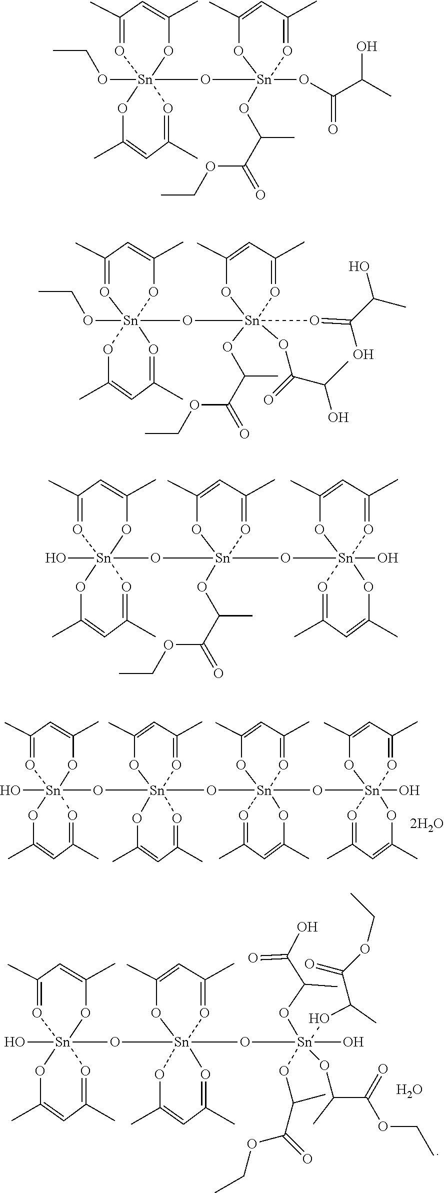

In some embodiments, the organic metal oxide oligomer may be the reaction product of reactants that include (i) a metal halide, a metal carboxylate, or a metal alkoxide, and (ii) a hydroxyl-containing solvent or a carbonyl-containing solvent having a boiling point less than 200° C. Exemplary metal halides include antimony halides, bismuth halides, cobalt halides, gallium halides, germanium halides, indium halides, manganese halides, tellurium halides, thallium halides, tin halides, tungsten halides, vanadium halides, zinc halides, or a combination thereof. Exemplary metal carboxylates include antimony carboxylates, bismuth carboxylates, cobalt carboxylates, gallium carboxylates, germanium carboxylates, indium carboxylates, manganese carboxylates, tellurium carboxylates, thallium carboxylates, tin carboxylates, tungsten carboxylates, vanadium carboxylates, zinc carboxylates, or a combination thereof. Exemplary metal alkoxides include antimony alkoxides, bismuth alkoxides, cobalt alkoxides, gallium alkoxides, germanium alkoxides, indium alkoxides, manganese alkoxides, tellurium alkoxides, thallium alkoxides, tin alkoxides, tungsten alkoxides, vanadium alkoxides, zinc alkoxides, or a combination thereof. The metal precursor may be a mixed-ligand metal compound, for example, having one or more of a halide ligand, a carboxylate ligand, an alkoxide ligand, or a combination thereof. For example, the organic metal oxide oligomer may be the reaction product of reactants that include (i) a tin halide, a tin carboxylate, a tin alkoxide, or a combination thereof, and (ii) a hydroxyl-containing solvent or a carbonyl-containing solvent having a boiling point less than 200° C. It is to be understood that the “reactants” may further include other components such as catalysts or the like, which may or may not be consumed during the course of the reaction.

In some embodiments, the organic metal oxide oligomer may be the reaction product of reactants that include (i) a tin halide, a tin carboxylate, a tin alkoxide, or a combination thereof, (ii) a hydroxyl-containing solvent or a carbonyl-containing solvent having a boiling point less than 200° C.; and (iii) a catalyst. Exemplary catalysts include amine containing compounds such as triethylamine, diisopropyl ethyl amine, or the like, azole compounds such as pyrazole and derivatives thereof, or imidazole and derivatives thereof, ammonium hydroxide, or a combination thereof.

In some embodiments, the organic metal oxide oligomer may be free of metal-carbon (M-C) bonds. In other words, in some embodiments, the metal centers of the organic metal oxide oligomer are not bonded to carbon.

The organic metal oxide oligomer may be included in the photoresist composition in an amount from 1 to 45 weight percent (wt %), more typically from 15 to 30%, 8 to 14 wt %, or from 1 to 7 wt %, based on total solids of the photoresist composition. In some embodiments, the photoresist composition may include two or more different organic metal oxide oligomers as described herein. For example, the photoresist composition may include one or more organic metal oxide oligomers in a combined amount from 1 to 45 wt %, more typically from 15 to 30%, 8 to 14 wt %, or from 1 to 7 wt %, based on total solids of the photoresist composition.

The photoresist composition includes a crosslinker including a photocleavable group, which for convenience may be referred to herein as the photocleavable crosslinker, wherein the crosslinker is structurally different from the organic metal oxide oligomer. As used herein, the term “photocleavable group” refers to a group in which a bond is cleaved by the action of light, optionally and typically with thermal treatment, resulting in formation of a polar group, such as a carboxylic acid or alcohol group. In some embodiments, the photocleavable group includes an oxime group. For example, the N—O bond(s) of the oxime group can readily undergo bond cleavage upon radiation exposure. Other exemplary photocleavable groups include those having moieties such as —C(═N)—C(═N)—, —C(═N)—C(═O)—, —C(═N)—C(—OH)—, —O—S—, —S—S—, and —N—S—, but embodiments are not limited thereto.

In some embodiments, the photocleavable group comprises one or more oxime groups. For example, the crosslinker may include a plurality of oxime groups. The oxime groups may each have cis and trans isomer forms, or they can exist as mixtures of isomers. It is to be understood that the crosslinker must function to crosslink two or more metal centers. Therefore, when the photocleavable group comprises a single oxime group, the crosslinker will further include one or more additional functional groups that are capable of crosslinking the metal centers. Exemplary additional functional groups include, but are not limited to, hydroxy, thiol, carboxylate, or the like, or a combination thereof.

In some embodiments, the photocleavable crosslinkers may be selected from one or more compounds of Formulae (3) to (6):

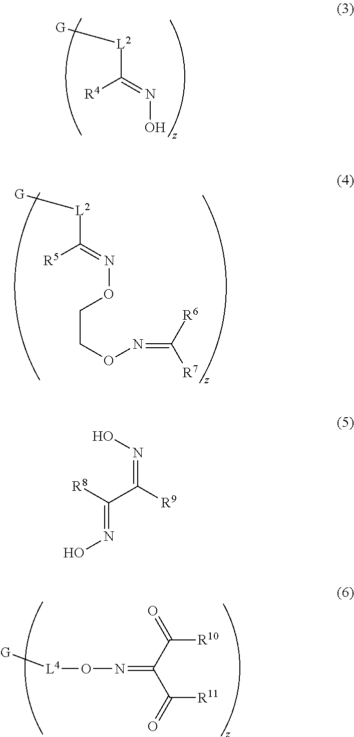

In Formulae (3), (4), and (6), G is a monovalent group or a polyvalent linking group. Exemplary polyvalent linking groups include —O—, —C(O)—, —C(O)O—, —S—, —S(O)—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formulae (3) and (4), each L² and each L³ is independently a single bond or one or more divalent linking groups. Each of the one or more divalent linking groups may be substituted or unsubstituted. Exemplary divalent linking groups may each independently be selected from —O—, —C(O)—, —C(O)O—, —S—, —S(O)—,—S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, L² and L³ may each independently be a single bond or substituted or unsubstituted C₁₋₂₀ alkylene, preferably a single bond or substituted or unsubstituted C₁₋₁₀ alkylene.

In Formula (6), each L⁴ is independently a single bond or one or more divalent linking groups. Each of the one or more divalent linking groups may be substituted or unsubstituted. Exemplary divalent linking groups may each independently be selected from —O—, —C(O)—, —C(O)O—, —S—, —S(O)—,—S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, L⁴ may each independently be a single bond or substituted or unsubstituted C₁₋₂₀ alkylene, preferably a single bond or substituted or unsubstituted C₁₋₁₀ alkylene.

In Formula (3), each R⁴ is independently hydrogen, hydroxyl, thiol, halogen, substituted or unsubstituted C₁₋₃₀ alkyl, substituted or unsubstituted C₃₋₃₀ cycloalkyl, substituted or unsubstituted C₃₋₃₀ cycloalkene, substituted or unsubstituted C₃₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₆₋₃₀ aryloxy, substituted or unsubstituted C₃₋₃₀ heteroaryl, substituted or unsubstituted C₄₋₃₀ alkylheteroaryl, substituted or unsubstituted C₄-30 heteroarylalkyl, or substituted or unsubstituted C₃₋₃₀ heteroaryloxy. For example, each R⁴ independently may be hydrogen, hydroxyl, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl.

In Formula (4), each R⁵, R⁶, and R⁷ is independently hydrogen, hydroxyl, thiol, halogen, substituted or unsubstituted C₁₋₃₀ alkyl, substituted or unsubstituted C₃₋₃₀ cycloalkyl, substituted or unsubstituted C₃₋₃₀ cycloalkene, substituted or unsubstituted C₃₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₆₋₃₀ aryloxy, substituted or unsubstituted C₃₋₃₀ heteroaryl, substituted or unsubstituted C₄₋₃₀ alkylheteroaryl, substituted or unsubstituted C₄-30 heteroarylalkyl, or substituted or unsubstituted C₃₋₃₀ heteroaryloxy. For example, each R⁵, R⁶, and R⁷ independently may be hydrogen, hydroxyl, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl.

Optionally, R⁶ and R⁷ may be bonded to each other via one or more divalent linking groups. Each of the one or more divalent linking groups may be substituted or unsubstituted. Exemplary divalent linking groups may each independently be selected from —O—, —C(O)—, —C(O)O—, —S—, —S(O)—,—S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (5), R¹ and R⁹ are each independently hydrogen, hydroxyl, thiol, halogen, substituted or unsubstituted C₁₋₃₀ alkyl, substituted or unsubstituted C₃₋₃₀ cycloalkyl, substituted or unsubstituted C₃₋₃₀ cycloalkene, substituted or unsubstituted C₃₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₆₋₃₀ aryloxy, substituted or unsubstituted C₃₋₃₀ heteroaryl, substituted or unsubstituted C₄₋₃₀ alkylheteroaryl, substituted or unsubstituted C₄-30 heteroarylalkyl, or substituted or unsubstituted C₃₋₃₀ heteroaryloxy. For example, each R⁸ and each R⁹ independently may be hydrogen, hydroxyl, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl.

Optionally, R⁸ and R⁹ may be bonded to each other via one or more divalent linking groups. Each of the one or more divalent linking groups may be substituted or unsubstituted. Exemplary divalent linking groups may each independently be selected from —O—, —C(O)—, —C(O)O—, —S—, —S(O)—,—S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formula (6), each R¹⁰ and R¹¹ is independently hydrogen, hydroxyl, thiol, halogen, substituted or unsubstituted C₁₋₃₀ alkyl, substituted or unsubstituted C₃₋₃₀ cycloalkyl, substituted or unsubstituted C₃₋₃₀ cycloalkene, substituted or unsubstituted C₃₋₃₀ heterocycloalkyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₆₋₃₀ aryloxy, substituted or unsubstituted C₃₋₃₀ heteroaryl, substituted or unsubstituted C₄₋₃₀ alkylheteroaryl, substituted or unsubstituted C₄-30 heteroarylalkyl, or substituted or unsubstituted C₃₋₃₀ heteroaryloxy. For example, each R¹⁰ and R¹¹ independently may be substituted or unsubstituted C₁-30 alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl.

Each of R⁴ to R¹¹ optionally further comprises one or more divalent linking groups as part of its structure. Each of the one or more divalent linking groups may be substituted or unsubstituted. Exemplary divalent linking groups may be selected from —O—, —C(O)—, —C(O)O—, —S—, —S(O)—, —S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

In Formulae (3) and (4), z is an integer from 1 to 6, typically from 1 to 4, and preferably from 1 to 3. In Formula (6), z is an integer from 2 to 6, typically from 2 to 4, and preferably 2 or 3.

When z is 2 or more, then adjacent two or more L² groups may be bonded to each other via one or more divalent linking groups. When z is 2 or more, then adjacent two or more L³ groups may be bonded to each other via one or more divalent linking groups. When z is 2 or more, then adjacent two or more R⁴ groups may be bonded to each other via one or more divalent linking groups. When z is 2 or more, then adjacent two or more R⁵ groups may be bonded to each other via one or more divalent linking groups. When z is 2 or more, then adjacent two or more of R⁶ and/or R⁷ groups may be bonded to each other via one or more divalent linking groups. Each of the one or more divalent linking groups may be substituted or unsubstituted. Exemplary divalent linking groups may each independently be selected from —O—, —C(O)—, —C(O)O—, —S—, —S(O)—,—S(O)₂—, —N(R′)—, —C(O)N(R′)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ may be hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

Exemplary crosslinkers that comprise a photocleavable group include the following:

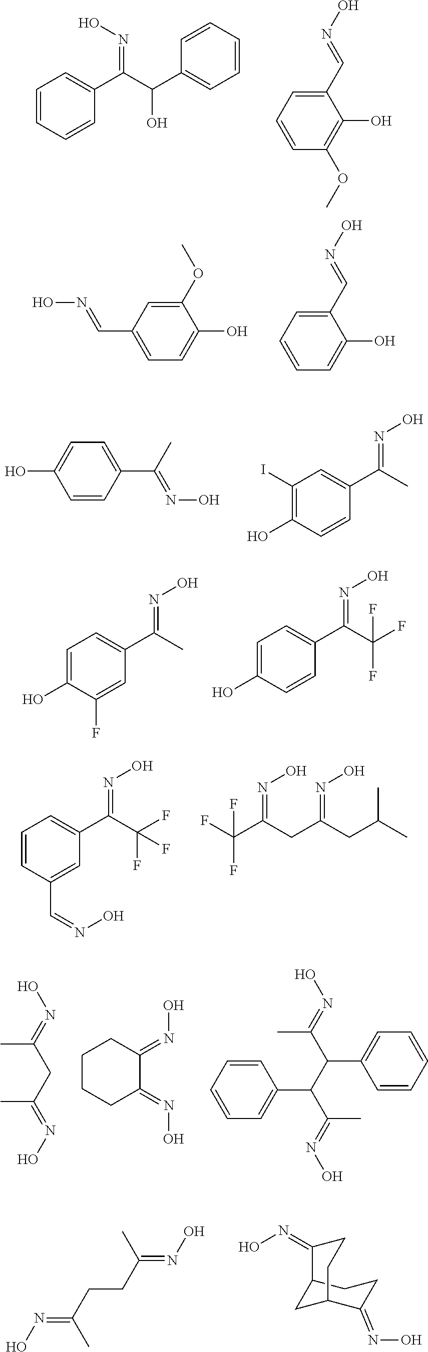

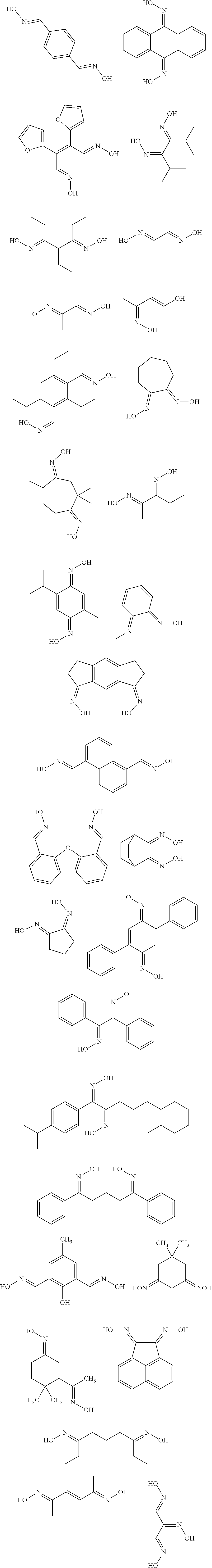

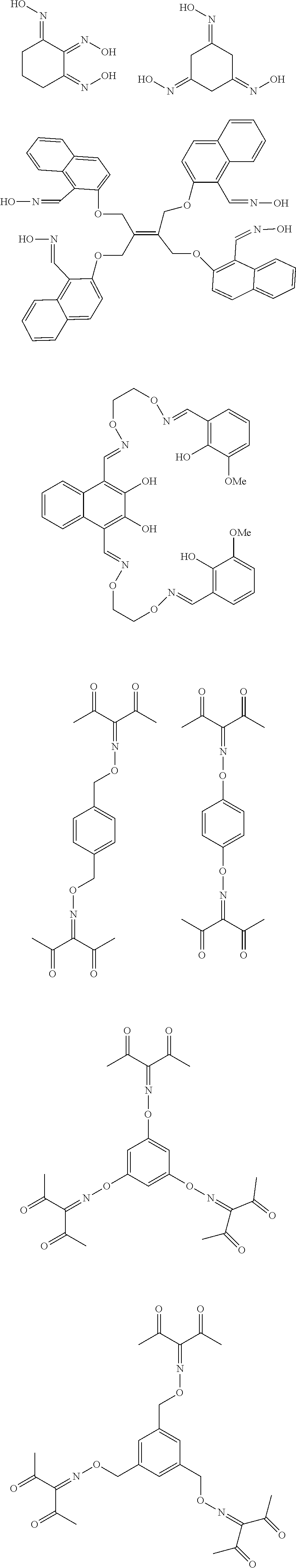

The crosslinkers that comprise a photocleavable group may be obtained from commercial sources or prepared by any suitable method. For example, such crosslinkers may be prepared as described in the Examples herein.

The crosslinker that includes the photocleavable groups is configured to crosslink the organic metal oxide oligomer upon curing (e.g., softbake) of the photoresist composition. The disposition of the photoresist composition on a substrate surface and the subsequent curing thereof is further described hereinbelow.

The crosslinker including the photocleavable group may be included in the photoresist composition in an amount from 1 to 25 weight percent (wt %), more typically from 1 to 20%, 1 to 14 wt %, or from 1 to 7 wt %, based on total solids of the photoresist composition. In some embodiments, the photoresist composition may include two or more different crosslinkers including different photocleavable groups as described herein. For example, the photoresist composition may include one or more crosslinkers including different photocleavable groups in a combined amount from 1 to 25 wt %, more typically from 1 to 20%, 1 to 14 wt %, or from 1 to 7 wt %, based on total solids of the photoresist composition.

In some embodiments, the photoresist composition may further include one or more additional crosslinkers that do not have a photocleavable group. The additional crosslinker may be a small molecule crosslinking agent or a polymeric crosslinking agent. Exemplary crosslinking agents include, but are not limited to, novolac resins, epoxy-containing compounds, melamine compounds, acetylacetonate compounds, guanamine compounds, isocyanate-containing compounds, thiol compounds, benzocyclobutenes, benzoxazines, and the like, and typically any of the foregoing having 2 or more, more typically 3 or more substituents selected from thiol, methylol, C₁₋₁₀ alkoxymethyl, acetylacetonate, and C₂₋₁₀ acyloxymethyl. In some embodiments, the additional crosslinker may include two or more thiol groups, such as 1,1,1-trimethylolpropane-tris(3-mercaptopropionate), pentaerythritol (3-mercaptopropionate), and 3,6-dioxa-1,8-octanedithiol.

Additional crosslinkers useful in the present invention include, for example: pentaerythritol tetrakis(3-mercaptobutylate) (“KarenzMT PE1”), trimethylolpropane-tris(3-mercaptobutylate) (“KarenzMT TPMB”), 1,3,5-tris[2-(3-mercaptobutanoyloxy)ethyl]-1,3,5-triazine-2,4,6(1H,3H,5H-trione (“KarenzMT NR1”), 1,4-bis(3-mercaptobutyroyloxy)butane (“KarenzMT BD1”), and combinations thereof.

The amount of the additional crosslinker in the photoresist composition may be from 0.01 to 40 wt %, for example, from 0.01 to 20 wt %, based on total solids of the photoresist composition.

In some embodiments, the weight ratio of the organic metal oxide oligomer to the photocleavable crosslinker may be from 4:1 to 1:4, preferably from 3:1 to 1:3 or from 2:1 to 1:2.

In some embodiments, the weight ratio of the organic metal oxide oligomer to the photocleavable crosslinker to the additional crosslinker may be from 4:1:0.1 to 4:1:1, for example, from 3:1:0.1 to 3:1:1, or from 2:1:0.01 to 2:1:1. In some embodiments, the weight ratio of the organic metal oxide oligomer to the photocleavable crosslinker to the additional crosslinker may be from 4:1:0.1 to 1:4:1, for example, from 3:1:0.1 to 1:3:1, or from 2:1:0.01 to 1:2:1.

The present photoresist composition may optionally include one or more surface leveling agents (or surfactants). Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Michigan USA) and PF-656 (Omnova Solutions, Beachwood, Ohio, USA). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, PA and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.). Such surfactants if used may be present in the composition in minor amounts, for example from greater than 0 to 1 wt % based on total solids of the photoresist composition.

In some aspects, the photoresist composition may further include a material that comprises one or more base-labile groups (a “base-labile material”). As referred to herein, base-labile groups are functional groups that can undergo cleavage reaction to provide polar groups such as hydroxyl, carboxylic acid, sulfonic acid, and the like, in the presence of an aqueous alkaline developer after exposure and post-exposure baking steps. The base-labile group will not react significantly (e.g., will not undergo a bond-breaking reaction) prior to a development step of the photoresist composition that comprises the base-labile group. Thus, for instance, a base-labile group will be substantially inert during pre-exposure soft-bake, exposure, and post-exposure bake steps. By “substantially inert” it is meant that ≤5%, typically 1%, of the base-labile groups (or moieties) will decompose, cleave, or react during the pre-exposure soft-bake, exposure, and post-exposure bake steps. The base-labile group is reactive under typical photoresist development conditions using, for example, an aqueous alkaline photoresist developer such as a 0.26 normal (N) aqueous solution of tetramethylammonium hydroxide (TMAH). For example, a 0.26 N aqueous solution of TMAH may be used for single puddle development or dynamic development, e.g., where the 0.26 N TMAH developer is dispensed onto an imaged photoresist layer for a suitable time such as 10 to 120 seconds (s). An exemplary base-labile group is an ester group, typically a fluorinated ester group. Preferably, the base-labile material is substantially not miscible with and has a lower surface energy than the first and/or second polymers and other solid components of the photoresist composition. When coated on a substrate, the base-labile material can thereby segregate from other solid components of the photoresist composition to a top surface of the formed photoresist layer.

In some aspects, the base-labile material may be a polymeric material, also referred to herein as a base-labile polymer, which may include one or more repeating units comprising one or more base-labile groups. For example, the base-labile polymer may comprise a repeating unit comprising 2 or more base-labile groups that are the same or different. A preferred base-labile polymer includes at least one repeating unit comprising 2 or more base-labile groups, for example a repeating unit comprising 2 or 3 base-labile groups.

The base-labile polymer may be prepared using any suitable methods in the art, including those described herein for the first and second polymers. For example, the base-labile polymer may be obtained by polymerization of the respective monomers under any suitable conditions, such as by heating at an effective temperature, irradiation with actinic radiation at an effective wavelength, or a combination thereof. Additionally, or alternatively, one or more base-labile groups may be grafted onto the backbone of a polymer using suitable methods.

In some aspects, the base-labile material is a single molecule comprising one more base-labile ester groups, preferably one or more fluorinated ester groups. The base-labile materials that are single molecules typically have a M_{w} in the range from 50 to 1,500 Da.

When present, the base-labile material is typically present in the photoresist compositions in an amount of from 0.01 to 10 wt % or 2 to 7 w %, typically from 1 to 5 wt %, based on total solids of the photoresist composition.

Additionally, or alternatively, to the base-labile polymer, the photoresist compositions may further include one or more organic polymers that are different from the organic metal oxide oligomer. The one or more additional polymers may include those well known in the photoresist art, for example, those chosen from polyacrylates, polyvinylethers, polyesters, polynorbornenes, polyacetals, polyethylene glycols, polyamides, polyacrylamides, polyphenols, novolacs, styrenic polymers, polyvinyl alcohols, or combinations thereof.

The photoresist composition may further include one or more additional, optional additives. For example, optional additives may include actinic and contrast dyes, anti-striation agents, plasticizers, speed enhancers, sensitizers, photo-decomposable quenchers (PDQ) (and, also known as photo-decomposable bases), basic quenchers, thermal acid generators, surfactants, and the like, or combinations thereof. If present, the optional additives are typically present in the photoresist compositions in an amount of from 0.01 to 10 wt %, based on total solids of the photoresist composition.

PDQs generate a weak acid upon irradiation. Exemplary photo-decomposable quenchers include, for example, photo-decomposable cations, and preferably those also useful for preparing strong acid generator compounds, paired with an anion of a weak acid (pKa>1) such as, for example, an anion of a C₁₋₂₀ carboxylic acid or C₁₋₂₀ sulfonic acid. Exemplary carboxylic acids include formic acid, acetic acid, propionic acid, tartaric acid, succinic acid, cyclohexanecarboxylic acid, benzoic acid, salicylic acid, and the like. Exemplary sulfonic acids include p-toluene sulfonic acid, camphor sulfonic acid, and the like. In a preferred embodiment, the photo-decomposable quencher is a photo-decomposable organic zwitterion compound such as diphenyliodonium-2-carboxylate.

The photo-decomposable quencher may be in non-polymeric or polymer-bound form. When in polymeric form, the photo-decomposable quencher is present in polymerized units on the first polymer or second polymer. The polymerized units containing the photo-decomposable quencher are typically present in an amount from 0.1 to 30 mole %, preferably from 1 to 10 mole % and more preferably from 1 to 2 mole %, based on total repeating units of the polymer.

Exemplary basic quenchers include, for example, linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers may be in non-polymeric or polymer-bound form. When in polymeric form, the quencher may be present in repeating units of the polymer. The repeating units containing the quencher are typically present in an amount of from 0.1 to 30 mole %, preferably from 1 to 10 mole % and more preferably from 1 to 2 mole %, based on total repeating units of the polymer.

Exemplary surfactants include fluorinated and non-fluorinated surfactants and can be ionic or non-ionic, with non-ionic surfactants being preferable. Exemplary fluorinated non-ionic surfactants include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In an aspect, the photoresist composition further includes a surfactant polymer including a fluorine-containing repeating unit. In other aspects, the photoresist composition further includes a surfactant polymer that excludes a fluorine-containing repeating unit.

Patterning methods using the photoresist compositions of the invention will now be described. Suitable substrates on which the photoresist compositions can be coated include electronic device substrates. A wide variety of electronic device substrates may be used in the present invention, such as: semiconductor wafers; polycrystalline silicon substrates; packaging substrates such as multichip modules; flat panel display substrates; substrates for light emitting diodes (LEDs) including organic light emitting diodes (OLEDs); and the like, with semiconductor wafers being typical. Such substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. Suitable substrates may be in the form of wafers such as those used in the manufacture of integrated circuits, optical sensors, flat panel displays, integrated optical circuits, and LEDs. Such substrates may be any suitable size. Typical wafer substrate diameters are 200 to 300 millimeters (mm), although wafers having smaller and larger diameters may be suitably employed according to the present invention. The substrates may include one or more layers or structures which may optionally include active or operable portions of devices being formed.

Typically, one or more lithographic layers such as a hardmask layer, for example, a spin-on-carbon (SOC), amorphous carbon, or metal hardmask layer, a CVD layer such as a silicon nitride (SiN), a silicon oxide (SiO), or silicon oxynitride (SiON) layer, an organic or inorganic underlayer, or combinations thereof, are provided on an upper surface of the substrate prior to coating a photoresist composition of the present invention. Such layers, together with an overcoated photoresist layer, form a lithographic material stack.

Optionally, a layer of an adhesion promoter may be applied to the substrate surface prior to coating the photoresist compositions. If an adhesion promoter is desired, any suitable adhesion promoter for polymer films may be used, such as silanes, typically organosilanes such as trimethoxyvinylsilane, triethoxyvinylsilane, hexamethyldisilazane, or an aminosilane coupler such as gamma-aminopropyltriethoxysilane. Particularly suitable adhesion promoters include those sold under the AP™ 3000, AP™ 8000, and AP™ 9000S designations, available from Qnity Electronics, Inc. (Marlborough, Massachusetts).

The photoresist composition may be coated on the substrate by any suitable method, including spin coating, spray coating, dip coating, doctor blading, or the like. For example, applying the layer of photoresist may be accomplished by spin coating the photoresist in solvent using a coating track, in which the photoresist is dispensed on a spinning wafer. During dispensing, the wafer is typically spun at a speed of up to 4,000 rotations per minute (rpm), for example, from 200 to 3,000 rpm, for example, from 1,000 to 2,500 rpm, for a period from 15 to 120 seconds to obtain a layer of the photoresist composition on the substrate. It will be appreciated by those skilled in the art that the thickness of the coated layer may be adjusted by changing the spin speed and/or the total solids of the composition. A photoresist composition layer formed from the compositions of the invention typically has a dried layer thickness from 1 nanometer (nm) to 120 micrometers (μm), preferably from greater than 5 nm to 110 μm, and more preferably from 6 to 100 μm. In some embodiments, the photoresist composition layer formed from the compositions may have a dried layer thickness from 10 nm to 5 μm, or from 3 to 20 μm.

The photoresist composition is typically next soft-baked to minimize the solvent content in the layer, thereby forming a tack-free coating and improving adhesion of the layer to the substrate. In addition, the softbake can facilitate the crosslinking of the organic metal oxide oligomer and the photocleavable crosslinker, and optionally the additional crosslinker. In some embodiments, the photocleavable crosslinker may form a bridging structure between two or more M centers of the organic metal oxide oligomer. Another aspect provides a coated substrate that includes a soft-baked photoresist composition layer, wherein the organic metal oxide oligomer and the crosslinker are crosslinked, and optionally wherein the organic metal oxide oligomer is further crosslinked by the additional crosslinker. The soft bake is performed, for example, on a hotplate or in an oven, with a hotplate being typical. The soft bake temperature and time will depend, for example, on the photoresist composition and thickness. The soft bake temperature is typically from 80 to 200° C., and more typically from 120 to 180° C. The soft bake time is typically from 10 seconds to 20 minutes, more typically from 30 seconds to 10 minutes, and still more typically from 30 seconds to 2 minutes. The heating time can be readily determined by one of ordinary skill in the art based on the ingredients of the composition.

The photoresist layer is next pattern-wise exposed to activating radiation to create a difference in solubility between exposed and unexposed regions. Reference herein to exposing a photoresist composition to radiation that is activating for the composition indicates that the radiation can form a latent image in the photoresist composition. The exposure is typically conducted through a patterned photomask that has optically transparent and optically opaque regions corresponding to regions of the resist layer to be exposed and unexposed, respectively. Such exposure may, alternatively, be conducted without a photomask in a direct writing method, typically used for e-beam lithography. The activating radiation typically has a wavelength of sub-400 nm, sub-300 nm, or sub-200 nm, with 248 nm (KrF), 193 nm (ArF), 13.5 nm (EUV) wavelengths or e-beam lithography being preferred. Preferably, the activating radiation is 13.5 nm (EUV) radiation. The methods find use in immersion or dry (non-immersion) lithography techniques. The exposure energy is typically from 1 to 200 millijoules per square centimeter (mJ/cm²), preferably from 10 to 100 mJ/cm² and more preferably from 10 to 50 mJ/cm², dependent upon the exposure tool and components of the photoresist composition.

Following exposure of the photoresist layer, a postexposure bake (PEB) of the exposed photoresist layer may be performed. The PEB can be conducted, for example, on a hotplate or in an oven, with a hotplate being typical. Conditions for the PEB will depend, for example, on the photoresist composition and layer thickness. The PEB is typically conducted at a temperature from 70 to 150° C., preferably from 75 to 120° C., and a time from 30 to 120 seconds. A latent image defined by the polarity-switched (exposed regions) and unswitched regions (unexposed regions) is formed in the photoresist. In some aspects, a PEB step is not performed.

The exposed photoresist layer is then developed with a suitable developer to selectively remove those regions of the layer that are soluble in the developer while the remaining insoluble regions form the resulting photoresist pattern relief image. In the case of a positive-tone development (PTD) process, the exposed regions of the photoresist layer are removed during development and unexposed regions remain. Conversely, in a negative-tone development (NTD) process, the exposed regions of the photoresist layer remain, and unexposed regions are removed during development. Application of the developer may be accomplished by any suitable method such as described above with respect to application of the photoresist composition, with spin coating being typical. The development time is for a period effective to remove the soluble regions of the photoresist, with a time of from 5 to 60 seconds being typical. Development is typically conducted at room temperature.

Suitable developers are organic solvent-based, meaning the cumulative content of organic solvents in the developer is 50 wt % or more, typically 95 wt % or more, 98 wt % or more, or 100 wt %, based on total weight of the developer. Suitable organic solvents for the developer include, for example, those chosen from ketones, esters, ethers, hydrocarbons, and mixtures thereof. In some embodiments, the developer is 2-heptanone, n-butyl acetate, or ethyl lactate. Typically, the developer includes ethyl lactate. In some embodiments, the developer is comprised of a mixture of one or more organic solvents. In some embodiments, the developer is comprised of a mixture of an organic solvent with acetic acid, typically 1-25 wt % relative to the organic solvent.

Preferably, the photoresist composition is used to provide a positive tone process. That is, in some embodiments, the photoresist composition may provide a resist relief image that is a positive resist relief image.

A coated substrate may be formed from the photoresist compositions of the invention. Such a coated substrate includes: (a) a substrate having one or more layers to be patterned on a surface thereof, and (b) a layer of the photoresist composition over the one or more layers to be patterned. The coated substrate may further include (c) a layer of the photoresist composition, wherein the organic metal oxide oligomer and the photocleavable crosslinker form a crosslinked structure.

The photoresist pattern may be used, for example, as an etch mask, thereby allowing the pattern to be transferred to one or more sequentially underlying layers by known etching techniques, typically by dry etching such as reactive ion etching. The photoresist pattern may, for example, be used for pattern transfer to an underlying hardmask layer which, in turn, is used as an etch mask for pattern transfer to one or more layers below the hardmask layer. If the photoresist pattern is not consumed during pattern transfer, it may be removed from the substrate by known techniques, for example, oxygen plasma ashing. The photoresist compositions may, when used in one or more such patterning processes, be used to fabricate semiconductor devices such as memory devices, processor chips (CPUs), graphics chips, optoelectronic chips, LEDs, OLEDs, as well as other electronic devices.

The invention is further illustrated by the following non-limiting examples.

### EXAMPLES

Unless otherwise noted, reactions were carried out under ambient atmospheric conditions. All chemicals were used directly from the supplier.

### (I) Synthesis of Organic Tin Oxide Materials

Reactor preparation. A 100 milliliters (mL), three-neck round bottom flask was used. One neck of the flask was connected with a thermal couple through which the temperature of the reactants in the flask was controlled with a heating controller. Heating of the reactor was through a heating mantle. Agitation of the reactor contents was provided through a magnetic stirring bar and a magnetic stirrer. Another neck of the flask was connected to a condenser without chilling fluid flow.

### Example 1

The reactor was charged with 6.788 grams (g) of tin chloride pentahydrate and 13.0 g of ethyl lactate. Heating of the reactor was begun together with stirring. The thermal controller was set to 80° C., and when the contents of the reactor reached the set temperature, then the heating timer was set for an additional 10.0 hours. At the end of this heating timer, the reactor was allowed to cool to room temperature with stirring. The solution obtained in the reactor was an organic tin oxide oligomer.

The solids content of the oligomers was determined by taking a 0.1 g sample of the oligomer solution and adding this to an aluminum pan of known weight. Then, about 0.3 mL of acetone was added to the pan to dilute the oligomer solution. The pan was placed on a hot plate at 90° C. for about 15 minutes to remove the solvents. The pan was then cooled to room temperature. When the pan cooled to room temperature, the weight of the dried oligomer was determined, and the percent solid content was calculated. This material was found to have 51.4 wt % solids in ethyl lactate.

### Example 2

This example was to synthesize organic tin oxide oligomer with pyrazole present in the reaction mixture as a catalyst. The reactor was charged with 6.0762 g of tin chloride pentahydrate, 0.4680 g of pyrazole, and about 12.0 g of ethyl lactate. Following the same procedure as in Example, after the reactant was heated for 10 hours with stirring, a more viscous solution was obtained. The dried oligomer was determined to contain 46.7 wt % solids in ethyl lactate.

### Example 3

This example was to increase the synthetic scale of the oligomer preparation in Example 2. 23.0066 g of tin chloride pentahydrate, 1.772 g of pyrazole, and about 46.0 g of ethyl lactate were added to the reactor. After the same 10-hours reaction at 80° C. as in the method of Example 1, the dried oligomer was found to contain 50.9 wt % solids in ethyl lactate.

### (II) Synthesis of Crosslinkable Compositions

### Example 4

0.5247 g of the organic tin oxide oligomer from Example 2 was combined with 12.2539 g of ethyl lactate to provide a 2.0 wt % solution of the organic tin oxide oligomer in ethyl lactate solvent. To the solution was added 0.2074 g of α-benzoin oxime as a photocleavable crosslinker to provide a solution having a ratio of the organic tin oxide oligomer to the photocleavable cross-linker of 1:0.85 by weight. The solution was filtered with a 0.2 μm PTFE syringe filter four times before being coated on three 8″ silicon wafers at 1500 rpm. The three wafers were respectively baked at 150° C., 160° C., and 170° C. for 60 seconds. The film thickness was in the range of 31.5 nm. The first test to the coated and cured films on the wafers was solvent stripping test using ethyl lactate for 60 seconds. No film retention was found for any of the three films. This result indicated that the films lacked sufficient cross-linking density for reaching a cross-linked network.

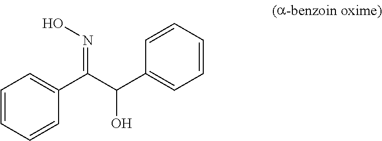 [SMILES: O/N=C(\c1ccccc1)C(O)c1ccccc1]

### Example 5

5.5862 g of the formulation from Example 4 was combined with 0.0232 g of an additional crosslinker pentaerythritol tetrakis(3-mercaptobutylate) (KarenzMT PE1).

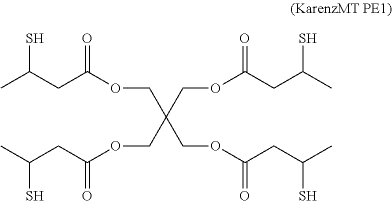 [SMILES: CC(S)CC(=O)OCC(COC(=O)CC(C)S)(COC(=O)CC(C)S)COC(=O)CC(C)S]

After being filtered with a 0.2 μm PTFE syringe filter, the solution was coated on two 8″ silicon wafers at 1500 rpm. The two coated wafers were then baked at 150° C. and 160° C., respectively, for 60 seconds. Shown in Table 1 are film thickness (FT) values before and after 60-second solvent (ethyl lactate) strip (develop), where the films were unexposed to radiation.

TABLE 1

| | 150° C. | 160° C. |
|---|---|---|
| FT before developing | 47.4 nm | 47.9 nm |
| FT after developing | 47.3 nm | 46.5 nm |

As shown in Table 2, excellent film retention was observed for the films baked at both temperatures.

The experiments were repeated using the compositions of Example 5, but with the films exposed to broadband radiation. Shown in Table 2 are film thickness (FT) values before and after 60-second solvent (ethyl lactate) strip (develop), where the films were exposed to broadband UV radiation.

TABLE 2

| | 150° C. | 160° C. |
|---|---|---|
| FT before developing | 48.0 nm | 46.9 nm |
| FT after developing | 1-15 nm | 10-15 nm |

Despite the notable film residue after development, the photocleavable nature of the cross-linker, α-benzoin oxime, was demonstrated.

### Example 6

Formulation A was prepared as an intermediate formulation by mixing 0.4022 g of the organic tin oxide oligomer from Example 2 with 0.1550 g of α-benzoin oxime and 15.2562 g of ethyl lactate. This formulation has a weight ratio of 1:0.8 for the organic tin oxide oligomer to the α-benzoin oxime photocleavable crosslinker.

Formulation B was prepared by mixing 7.3012 g of Formulation A with 0.0106 g of an additional crosslinker (KarenzMT PE1) to provide a 1:0.8:0.1 weight ratio of the organic tin oxide oligomer to α-benzoin oxime photocleavable crosslinker to additional crosslinker.

Formulation C was prepared by mixing 7.3042 g of Formulation A with 0.0174 g of an additional crosslinker (KarenzMT PE1) to end up with a 1:0.8:0.15 weight ratio of the organic tin oxide oligomer to α-benzoin oxime photocleavable crosslinker to additional crosslinker.

Formulations B and C were filtered with a 0.2 μm PTFE syringe filter before being coated on 8″ silicon wafers. The process included 1500 rpm spin coating and 150° C. baking for 60 seconds. The same broadband UV exposure as Example 5 was conducted on a half portion of each wafer, and each portion of the wafers was developed in ethyl lactate for 60 seconds. Film thickness was measured and recorded in Tables 3 (unexposed) and Table 4 (exposed).

TABLE 3

| | Formulation B | Formulation C |
|---|---|---|
| FT before developing | 32.8 nm | 32.2 nm |
| FT after developing | 32.5 nm | 32.0 nm |

TABLE 4

| | Formulation B | | Formulation C | |
|---|---|---|---|---|
| FT before developing | 31.9 | nm | 34.8 | nm |
| FT after developing | ~3 | nm | ~3 | nm |

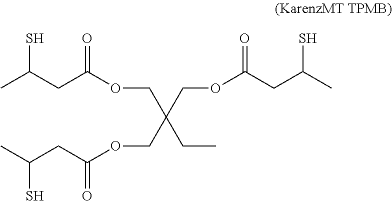 [SMILES: CCC(COC(=O)CC(C)S)(COC(=O)CC(C)S)COC(=O)CC(C)S]

From Table 3 and 4, the residual film thickness was reduced significantly in the exposed regions while the films in the unexposed region showed excellent solvent resistance.

An EUV flood exposure test was conducted with 16 mJ/cm² energy dosage, to evaluate the photocleavable property of the cross-linker, α-benzoin oxime. Detailed results are summarized in Tables 5 (unexposed) and 6 (exposed).

TABLE 5

| | Formulation B | Formulation C |
|---|---|---|
| FT before developing | 27.0 nm | 27.0 nm |
| FT after developing | 25.3 nm | 27.7 nm |

TABLE 6

| | Formulation B | | Formulation C | |
|---|---|---|---|---|
| FT before developing | 26.7 | nm | 28.0 | nm |
| FT after developing | 5.3 | nm | 8.7 | nm |

### Example 7

Formulations were prepared with constant loading of the organic tin oxide oligomer and α-benzoin oxime photocleavable crosslinker, but contained varied amounts of the additional crosslinker (KarenzMT PE1). Listed in Table 7 are the detailed formulations, where the organic tin oligomer was provided as a 50.9 wt % solution in ethyl lactate.

TABLE 7

| | Tin | Photocleavable | Additional | Ethyl |
|---|---|---|---|---|
| | Oligomer | Crosslinker | Crosslinker | Lactate |
| Sample | (g) | (g) | (g) | (g) |
| 7A | 0.295 | 0.210 | 0.030 | 9.565 |
| 7B | 0.295 | 0.210 | 0.015 | 9.580 |
| 7C | 0.295 | 0.210 | 0.011 | 9.584 |
| 7D | 0.295 | 0.210 | 0.008 | 9.587 |
| 7E | 0.295 | 0.210 | 0.006 | 9.589 |
| 7F | 0.295 | 0.210 | 0.005 | 9.590 |
| 7G | 0.295 | 0.210 | 0.003 | 9.592 |
| 7H | 0.295 | 0.210 | 0.000 | 9.595 |

The samples were filtered with a 0.2 μm PTFE syringe filter before being coated on 8″ silicon wafers at 1500 rpm, followed by a baking at 150° C. for 60 seconds. The films were then exposed in broadband UV lamps for UV exposure and then stripped (developed) in ethyl lactate for 60 second. Shown in Table 8 are film thickness (FT) values before and after the 60-second ethyl lactate strip (development) for the exposed and unexposed regions of the films (UFTL=unexposed film thickness loss).

TABLE 8

| | FT before | FT after develop | FT after develop | |
|---|---|---|---|---|
| Sample | develop nm | (unexposed), nm | (exposed), nm | UFTL, nm |
| 7A | 44.40 | 44.10 | 10.36 | 0.30 |
| 7B | 45.45 | 42.28 | 4.15 | 3.17 |
| 7C | 45.65 | 43.22 | 2.45 | 2.43 |
| 7D | 46.7 | 41.70 | 0.88 | 5.00 |
| 7E | 45.97 | 40.04 | 0.7 | 5.93 |
| 7F | 45.015 | 38.185 | 0.15 | 6.83 |
| 7G | 44.14 | 32.04 | 0 | 12.1 |
| 7H | 44.05 | 21.08 | 0.59 | 22.97 |

### Example 8

Formulations were prepared with the same loading of the organic tin oxide oligomer and additional crosslinker (KarenzMT PE1), but with varied amounts of α-benzoin oxime photocleavable crosslinker. The detailed formulations are listed in the Table 9, where the organic tin oligomer was provided as a 50.9 wt % solution in ethyl lactate.

TABLE 9

| | Tin | Photocleavable | Additional | Ethyl |
|---|---|---|---|---|
| Sample | Oligomer (g) | Crosslinker (g) | Crosslinker (g) | lactate (g) |
| 8A | 0.295 | 0.210 | 0.008 | 14.487 |
| 8B | 0.295 | 0.180 | 0.008 | 14.517 |
| 8C | 0.295 | 0.150 | 0.008 | 14.547 |

The samples in the Table 9 were filtered with a 0.2 μm PTFE syringe filter before being coated on 8-inch silicon wafers at 1500 rpm. Each of the coated wafers were then baked at 150° C. for 60 seconds. The films were then exposed to broadband UV lamps for UV exposure and then developed in a solvent (ethyl lactate) for 60 seconds. Shown in Table 10 are film thickness (FT) values before and after the 60-second ethyl lactate strip (development) for the exposed and unexposed regions of the films (UFTL=unexposed film thickness loss).

TABLE 10

| | FT before | FT after develop | FT after develop | |
|---|---|---|---|---|
| Sample | develop, nm | (unexposed), nm | (exposed), nm | UFTL, nm |
| 8A | 28.79 | 22.32 | 0.38 | 6.48 |
| 8B | 27.71 | 16.62 | 0 | 11.09 |
| 8C | 25.24 | 2.16 | 0 | 23.08 |

### Example 9

Another photocleavable crosslinker, 2,4-pentanedione dioxime, was used in addition to the photocleavable cross-linker α-benzoin oxime. The detailed formulation is given in Table 11, where the organic tin oligomer is provided as a 50.9 wt % solution in ethyl lactate.

TABLE 11

| | Tin | Photocleavable | Additional | Additional | Ethyl |
|---|---|---|---|---|---|
| | Oligomer | crosslinker | Crosslinker | photocleavable | lactate |
| Sample | (g) | (g) | (g) | crosslinker (g) | (g) |
| 9A | 0.295 | 0.210 | 0.003 | 0.038 | 9.454 |

Following the same processes including filtration with a 0.2 PTFE syringe filter, 1500 rpm spin coating, 150° C./60 sec bake, broadband UV exposure, 60-second ethyl lactate strip (development), the film thickness values of the processed films are listed in Table 12.

TABLE 12

| | FT before | FT after develop | FT after develop | |
|---|---|---|---|---|
| Sample | develop, nm | (unexposed), nm | (exposed), nm | UFTL, nm |
| 9A | 54.49 | 54.10 | 0.31 | 0.39 |

### Example 10

The formulation in Example 9 was further optimized by reducing the amount of the additional photocleavable crosslinker 2,4-pentanedione dioxime, with its detailed Formulation given in Table 13, where the organic tin oligomer was provided as a 50.9 wt % solution in ethyl lactate.

TABLE 13

| | Tin | Photocleavable | Additional | Additional | Ethyl |
|---|---|---|---|---|---|
| | Oligomer | crosslinker | Crosslinker | photocleavable | lactate, |
| Sample | (g) | (g) | (g) | crosslinker (g) | g |
| 10A | 0.295 | 0.210 | 0.003 | 0.023 | 14.469 |
| 10B | 0.295 | 0.210 | 0.003 | 0.015 | 14.477 |

Following the same processes including filtration with a 0.2 PTFE syringe filter, 1500 rpm spin coating, 150° C./60 sec bake, broadband UV exposure, 60-second ethyl lactate strip (development), the film thickness values of the processed films are listed in Table 14.

TABLE 14

| | FT before | FT after develop | FT after develop | |
|---|---|---|---|---|
| Sample | develop, nm | (unexposed), nm | (exposed), nm | UFTL, nm |
| 10A | 29.21 | 25.24 | 0.00 | 3.97 |
| 10B | 28.57 | 23.61 | 0.00 | 4.96 |

Sample 10A was further tested with EUV flood exposure to derive a contrast curve as EUV responses to the formulation. Shown in Table 15 are the film thickness values corresponding to different EUV exposure dosages.

TABLE 15

| | EUV dosages and film thickness after exposure | | | | | | |
|---|---|---|---|---|---|---|---|
| FT before | 0 mJ/ | 2 mJ/ | 4 mJ/ | 6 mJ/ | 8 mJ/ | 10 mJ/ | 12 mJ/ |
| exposure | cm² | cm² | cm² | cm² | cm² | cm² | cm² |
| 29.77 nm | 24 nm | 21.33 nm | 7.33 nm | 4.33 nm | 1 nm | 1 nm | 1.33 nm |

### Example 11

Sample 11A was prepared as a 2 wt % solids content by combining the organic tin oxide oligomer (prepared in Example 3, at 50.9 wt % in ethyl lactate solution) with 2,4-pentanedione dioxime and α-benzoin oxime in a weight ratio of 1:1:0.1 in ethyl lactate.

Sample 11B was prepared as a 2 wt % solids content by combining the organic tin oxide oligomer (prepared in Example 3, at 50.9 wt % in ethyl lactate solution) with 1,2-cyclohexanedione dioxime in a weight ratio of 1:1 in ethyl lactate.

Sample 11C was prepared as a 2 wt % solids content by combining the organic tin oxide oligomer (prepared in Example 3, at 50.9 wt % in ethyl lactate solution) with 2,4-pentanedione dioxime and α-benzoin oxime in a weight ratio of 1:1.5:0.1 in ethyl lactate.

Sample 11D was prepared as a 2 wt % solids content by combining the organic tin oxide oligomer (prepared in Example 3, at 50.9 wt % in ethyl lactate solution) with 2,4-pentanedione dioxime and α-benzoin oxime in a weight ratio of 1:2:0.1 in ethyl lactate.

Sample 11E was prepared as a 2 wt % solids content by combining the organic tin oxide oligomer (prepared in Example 3, at 50.9 wt % in ethyl lactate solution) with 1,2-cyclohexanedione dioxime in a weight ratio of 1:1.5 in ethyl lactate.

Sample 11F was prepared as a 2 wt % solids content by combining the organic tin oxide oligomer (prepared in Example 3, at 50.9 wt % in ethyl lactate solution) with 1,2-cyclohexanedione dioxime in a weight ratio of 1:2 in ethyl lactate.

Samples 11A to 11F were filtered with a 0.2 μm PTFE syringe filter followed by spin coating at 1000 rpm onto an 8-inch silicon wafer. The coated films were baked at different temperatures before ethyl lactate solvent strip (develop) for 60 seconds. Shown in Tables 16 and 17 are the film thickness (FT) of the films before and after the 60-second ethyl lactate strip, which also provides the soft baking temperatures.

TABLE 16

| | Bake Temp, ° C., | FT before | FT after |
|---|---|---|---|
| Sample | 60 seconds | develop, nm | develop, nm |
| 11A | 130 | 13.8 | 0 |
| | 140 | 12.8 | 0 |
| | 150 | 12.6 | 0 |
| | 160 | 12.8 | 0 |
| 11C | 130 | 13.8 | 0 |
| | 140 | 11.7 | 0 |
| | 150 | 10.9 | 0 |
| | 160 | 12.5 | 0 |
| 11D | 130 | 11 | 0 |
| | 140 | 10.5 | 0 |
| | 150 | 9.3 | 0 |
| | 160 | 9.0 | 0 |

TABLE 17

| | Bake Temp, ° C., | FT before | FT after |
|---|---|---|---|
| Sample | 60 seconds | develop, nm | develop, nm |
| 11B | 130 | 21.1 | 0 |
| | 140 | 20.2 | 0 |
| | 150 | 19 | 0 |
| | 160 | 18.7 | 0 |
| 11E | 130 | 21 | 0 |
| | 140 | 18.7 | 0 |
| | 150 | 17.3 | 0 |
| | 160 | 16.1 | 0 |
| 11F | 130 | 19.2 | 0 |
| | 140 | 17 | 0 |
| | 150 | 15.7 | 0 |
| | 160 | 14.5 | 0 |

### Example 12

Formulation 12A was prepared as a 4 wt % solids content by combining the organic tin oxide oligomer (prepared in Example 3, at 50.9 wt % in ethyl lactate solution) with 2,4-pentanedione dioxime and an additional crosslinker (KarenzMT TPMB) in a weight ratio of 1:1.4:0.05 in ethyl lactate.

Formulation 12B was prepared as a 4 wt % solids content by combining the organic tin oxide oligomer (prepared in Example 3, at 50.9 wt % in ethyl lactate solution) with 1,2-cyclohexanedione dioxime and an additional crosslinker (KarenzMT TPMB) in a weight ratio of 1:1.4:0.05 in ethyl lactate.

Formulation 12C was prepared as a 4 wt % solids content by combining the organic tin oxide oligomer (prepared in Example 3, at 50.9 wt % in ethyl lactate solution) with α-benzoin oxime and an additional crosslinker (KarenzMT TPMB) in a weight ratio of 1:1.4:0.05 in ethyl lactate.

Following the same process as in Example 11, the film thickness before and after the 60-seconds ethyl lactate strip is provided in Table 18 for Samples 12A to 12C. The data provides evaluations in both unexposed regions and broadband UV exposed regions.

TABLE 18

| | Bake | Unexposed region | | exposed region | |
|---|---|---|---|---|---|
| | Temp, | | FT after | | FT after |
| Sample | ° C. | FT, nm | develop, nm | FT, nm | develop, nm |
| 12A | 130 | 18 | 0 | 18 | 0 |
| | 140 | 16 | 0 | 16 | 0 |
| | 150 | 16 | 0.8 | 16 | 0 |
| | 160 | 15 | 1.5 | 15 | 0 |
| 12B | 130 | 36 | 0.8 | 35 | 1 |
| | 140 | 32 | 2 | 32 | 1.5 |
| | 150 | 30 | 6 | 30 | 2 |
| | 160 | 28 | 23 | 27 | 4 |
| 12C | 130 | 53 | 46 | 41 | 0 |
| | 140 | 52 | 44 | 39 | 0 |
| | 150 | 53 | 41 | 38 | 0.7 |
| | 160 | 58 | 47 | 40 | 3 |

### Example 13

The Formulation 13A to 13E as tested in this example were prepared using the composition of Example 7A. The different test conditions (baking temperatures and develop times) are provided in Table 19.

The samples were filtered with a 0.2 μm PTFE syringe filter before being coated on 8-inch silicon wafers at 1500 rpm. Each coated wafer was baked at different temperatures as recorded in Table 20 for 60 seconds. The films were then exposed to a broadband UV source before solvent (ethyl lactate) strip (development) for 30 or 60 seconds.

Film thickness values before and after the solvent development for films baked at different temperatures are shown in Table 19.

TABLE 19

| | | | FT | FT after | FT after | | |
|---|---|---|---|---|---|---|---|
| | Bake | | before | develop | develop | | |
| | Temp, | Develop | Dev, | (unexposed), | (exposed), | UFTL | loss |
| Sample | ° C | time, s | nm | nm | nm | (nm) | (%) |
| 13A | 130 | 30 | 49.16 | 44.56 | 8.79 | 4.60 | 9.36 |
| 13B | 130 | 60 | 50.19 | 43.06 | 8.67 | 7.14 | 14.22 |
| 13C | 140 | 30 | 47.01 | 45.45 | 8.81 | 1.56 | 3.32 |
| 13D | 150 | 30 | 46.66 | 45.62 | 8.65 | 1.05 | 2.24 |
| 13E | 160 | 30 | 46.24 | 45.19 | 8.92 | 1.05 | 2.26 |

### Example 14

Formulations 14A to 14C were prepared at a total solids content of 4 wt % in ethyl lactate with a weight ratio of the organic tin oxide oligomer to α-benzoin oxime to additional crosslinker of 1:1.4:0.2. The organic tin oxide oligomer was from Example 3.

Sample 14A was prepared by combining 0.295 g of the organic tin oxide oligomer (50.9% in ethyl lactate from Example 3) with 0.210 g of α-benzoin oxime, 0.03 g of the additional crosslinker (KarenzMT PE1) and 0.946 g of ethyl lactate. Samples 14B and 14C were prepared similarly but replaced KarenzMT PE1 with the same amount of KarenzMT BD1 or KarenzMT TPMB, respectively. Formulations 14A to 14C are detailed in Table 20.

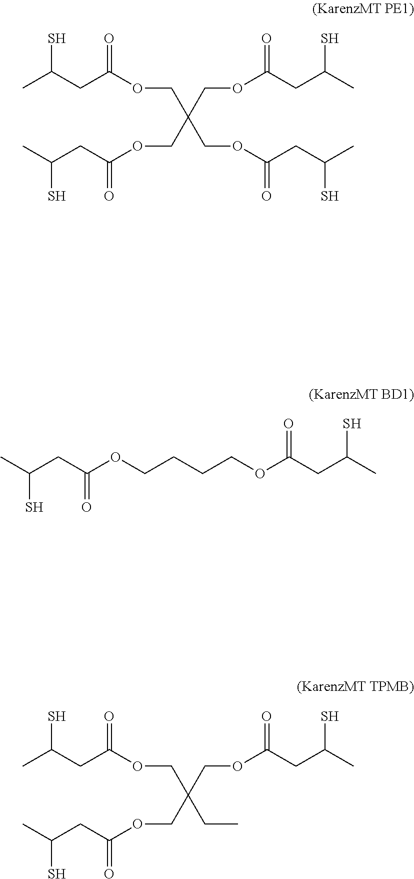

TABLE 20

| Sample | KarenzMT PE1 | KarenzMT BD1 | KarenzMT TPMB |
|---|---|---|---|
| 14A | x | | |
| 14B | | x | |
| 14C | | | x |

The samples were filtered with a 0.2 μm PTFE syringe filter before being coated on 8-inch silicon wafers at 1500 rpm, followed by a baking at 150° C. for 60 seconds. The films were then exposed in broadband UV lamps for UV exposure and then stripped (developed) in ethyl lactate for 30 seconds. Shown in Table 21 are film thickness (FT) values before and after the 30-second ethyl lactate strip (development) for the exposed and unexposed regions of the films (UFTL=unexposed film thickness loss).

TABLE 21

| Sample | FT before | FT after develop | FT after develop | |
|---|---|---|---|---|
| ID | develop, nm | (unexposed), nm | (exposed), nm | UFTL, nm |
| 14A | 46.66 | 45.62 | 8.65 | 1.05 |
| 14B | 50.17 | 48.92 | 0.01 | 1.25 |
| 14C | 47.25 | 46.75 | 8.73 | 0.51 |

### Example 15

Formulations 15A to 15F were prepared at a total solids content of 4 wt % in ethyl lactate with a weight ratio of the organic tin oxide oligomer to α-benzoin oxime to additional crosslinker (KarenzMT BD1) in the weight ratios that are specified in Table 22. The organic tin oxide oligomer was from Example 3.

TABLE 22

| | Weight ratio of the organic tin |
|---|---|
| | oxide oligomer/photocleavable |
| Sample | crosslinker/additional crosslinker |
| 15A | 1:1.4:0.2 |
| 15B | 1:1.2:0.2 |
| 15C | 1:1:0.2 |
| 15D | 1:0.8:0.2 |
| 15E | 1:0.6:0.2 |
| 15F | 1:0.4:0.2 |

The samples were filtered with a 0.2 μm PTFE syringe filter before being coated on 8-inch silicon wafers at 1500 rpm, followed by a baking at 150° C. for 60 seconds. The films were then exposed in broadband UV lamps for UV exposure and then stripped (developed) in ethyl lactate for 30 seconds. Shown in Table 23 are film thickness (FT) values before and after the 30-second ethyl lactate strip (development) for the exposed and unexposed regions of the films (UFTL=unexposed film thickness loss).

TABLE 23

| | | FT after | FT after | |
|---|---|---|---|---|
| | FT before | development | development | |
| Sample | develop, nm | (unexposed), nm | (exposed), nm | UFTL, nm |
| 15A | 50.17 | 48.92 | 0.01 | 1.25 |
| 15B | 45.47 | 44.58 | 0.81 | 0.89 |
| 15C | 40.57 | 43.28 | 0.62 | 1.69 |
| 15D | 36.91 | 36.54 | 0.09 | 0.37 |
| 15E | 32.93 | 32.8 | 0.18 | 0.13 |
| 15F | 24.56 | 7.01 | 0 | 17.53 |

Sample 15E was further tested with EUV exposure. Shown in Table 24 are the film thickness values under different EUV exposure dosages. Developing time was 30 seconds with ethyl lactate.

TABLE 24

| | FT after develop at different EUV energy mJ/cm2 | | | | | | |
|---|---|---|---|---|---|---|---|
| FT before | 0 | 2 | 4 | 6 | 8 | 10 | 12 |
| develop | mJ/ | mJ/ | mJ/ | mJ/ | mJ/ | mJ/ | mJ/ |
| | cm² | cm² | cm² | cm² | cm² | cm² | cm² |
| 29 nm | 26 nm | 19.3 nm | 12.7 nm | 10 nm | 4 nm | 2 nm | 2 nm |

### Example 16

### Synthesis of Dioxime Crosslinker D1

The dioxime crosslinker, D1, was synthesized according to the following reaction scheme:

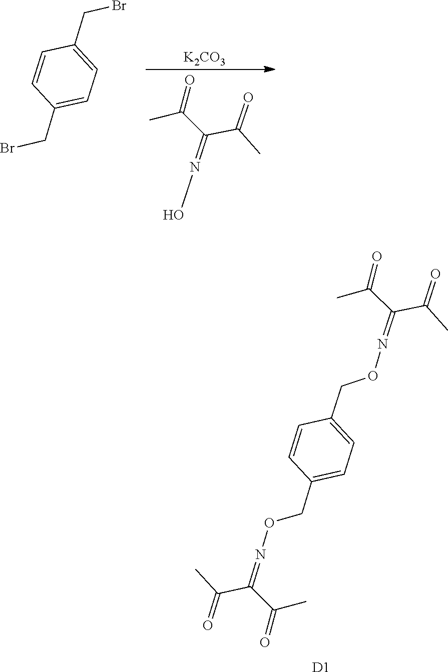

In a 100-mL round bottom flask, to 1.5 g of acetylacetonate-oxime (acac-oxime) and 1.53 g of α,α′-dibromo-p-xylene in 45 mL of acetone was added 1.6 g of potassium carbonate, and the reaction mixture was stirred at room temperature for 3.5 hours. The reaction mixture was then poured into a separatory funnel. Water and brine were added, and the contents were extracted with ethyl acetate (EtOAc) (4×). The combined organic extracts were dried with sodium sulfate, filtered, and concentrated under reduced pressure to give a white solid that was triturated twice with 3:1 hexanes:EtOAc. The yield was 1.89 g of the dioxime crosslinker D1.

The organic tin oxide oligomer from Example 2 was combined with D1 as a photocleavable crosslinker to provide a solution having a ratio of the organic tin oxide oligomer to the photocleavable crosslinker of 1:0.3 by weight. Ethyl lactate was added to provide a 4 wt % solids solution in ethyl lactate. The solution was filtered with a 0.2 μm PTFE syringe filter before being coated on three 8″ silicon wafers at 1500 rpm. The coated wafers were then baked at 160° C., 165° C., or 170° C., respectively as indicated in Table 25, for 60 seconds each. The test results shown in Table 25 are the initial film thickness before development, and the film thicknesses of the unexposed and exposed regions after development. The developer was ethyl lactate and the development was steady in a beaker for 60 seconds followed by jet air drying. The UV exposure was to broadband UV radiation.

TABLE 25

| Temp | FT before | FT after develop | FT after develop |
|---|---|---|---|
| (° C.) | develop, nm | (unexposed), nm | (exposed), nm |
| 160 | 38.3 | 8.6 | 0 |
| 165 | 38.9 | 18.0 | 0.6 |
| 170 | 37.1 | 25.0 | 0.6 |

### Example 17

### Synthesis of Trioxime Crosslinker T1

The trioxime crosslinker, T1, was synthesized through the following reaction scheme:

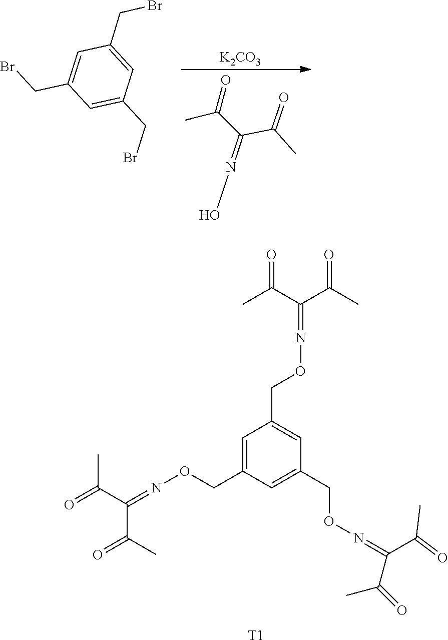

In a 1-L round bottom flask, 6.10 g of acac-oxime was dissolved in 142.8 g of acetone, and then 3.701 g of tribromomethyl benzene and 5.20 g of potassium carbonate were added thereto at room temperature. After 5 hours of stirring at room temperature, the reaction mixture was poured into a separatory funnel. Water was added to the funnel, and the contents were extracted with EtOAc (4 x). The combined extracts were dried with sodium sulfate, filtered, and concentrated under reduced pressure to give a white sticky solid, which was then purified through recrystallization. In the recrystallization process, 1 g of the trioxime crosslinker crude product was dissolved in 2.5 g of ethyl acetate in a 20 mL glass vial. Then, 10 g of hexanes was added to the vial and the mixture was heated to 40° C. Ethyl acetate was then added to the mixture dropwise until a clear solution was obtained. The heating was removed and the vial was placed in the refrigerator at 4° C. until a white solid precipitated out of the solution. The solvents were removed to provide the purified trioxime crosslinker T1.

The organic tin oxide oligomer from Example 2 was combined with the trioxime crosslinker T1 as a photocleavable crosslinker to provide a solution having a ratio of the organic tin oxide oligomer to the photocleavable crosslinker of 1:0.2 by weight. Ethyl lactate was added to provide a 3 wt % solids solution in ethyl lactate. The solution was filtered with a 0.2 μm PTFE syringe filter before being coated on an 8″ silicon wafer at 1500 rpm. The coated wafer was then baked at 175° C. for 60 seconds. The test results shown in Table 26 are the initial film thickness before development, and the film thickness of the unexposed and exposed regions after development. The developer was ethyl lactate and the development was steady in a beaker for 60 seconds followed by jet air drying. The UV exposure was to broadband UV radiation.

TABLE 26

| Temp | FT before | FT after develop | FT after develop |
|---|---|---|---|
| (° C.) | develop, nm | (unexposed), nm | (exposed), nm |
| 175 | 38.4 | 32.1 | 0.1 |

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist composition, comprising:
an organic metal oxide oligomer comprising a M-O-M bond, wherein M comprises a metal;
a crosslinker comprising a photocleavable group, wherein the crosslinker is structurally different from the organic metal oxide oligomer; and
a solvent,
wherein the solvent is present in the photoresist composition in an amount greater than 50 wt %, based on total weight of the photoresist composition.

2. The photoresist composition of claim 1, wherein M comprises tin, germanium, indium, antimony, tellurium, bismuth, or a combination thereof.

3. The photoresist composition of claim 1, wherein M comprises tin.

4. The photoresist composition of claim 1, wherein the organic metal oxide oligomer is the reaction product of reactants comprising:
(i) a tin halide, a tin carboxylate, or a tin alkoxide, and
(ii) a hydroxyl-containing solvent or a carbonyl-containing solvent having a boiling point less than 200° C.

5. The photoresist composition of claim 1, wherein the organic metal oxide oligomer is free of M-C bonds.

6. The photoresist composition of claim 1, wherein the photocleavable group comprises one or more oxime groups.

7. The photoresist composition of claim 1, further comprising an additional crosslinker that is structurally different from the crosslinker comprising the photocleavable group.

8. The photoresist composition of claim 7, wherein the additional crosslinker comprises two or more thiol groups.

9. A pattern formation method, comprising:
(a) applying a layer of the photoresist composition of claim 1 on a substrate to form a photoresist composition layer;
(b) soft-baking the photoresist composition layer to crosslink the organic metal oxide oligomer and the crosslinker to form a soft-baked photoresist composition layer;
(c) exposing the soft-baked photoresist composition layer to activating radiation to form a post-exposure photoresist composition layer; and
(d) developing the post-exposure photoresist composition layer to provide a resist relief image.

10. The pattern formation method of claim 9, wherein the resist relief image is a positive resist relief image.

11. The pattern formation method of claim 9, wherein in the photoresist composition, M comprises tin, germanium, indium, antimony, tellurium, bismuth, or a combination thereof.

12. The pattern formation method of claim 9, wherein in the photoresist composition, M comprises tin.

13. The pattern formation method of claim 9, wherein in the photoresist composition, the organic metal oxide oligomer is the reaction product of reactants comprising:
(i) a tin halide, a tin carboxylate, or a tin alkoxide, and
(ii) a hydroxyl-containing solvent or a carbonyl-containing solvent having a boiling point less than 200° C.

14. The pattern formation method of claim 9, wherein in the photoresist composition, the organic metal oxide oligomer is free of M-C bonds.

15. The pattern formation method of claim 9, wherein in the photoresist composition, the photocleavable group comprises one or more oxime groups.

16. The pattern formation method of claim 9, wherein the photoresist composition further comprises an additional crosslinker that is structurally different from the crosslinker comprising the photocleavable group.

17. The pattern formation method of claim 16, wherein the additional crosslinker comprises two or more thiol groups.
